(19) United States
(12) Patent Application Publication
(10) Pub. No.: US 2007/0093014 A1
(43) Pub. Date: Apr. 26, 2007

(54) Method for preventing doped boron in a dielectric layer from diffusing into a substrate

(75) Inventors: Chia-Shun Hsiao, Hsinchu (TW); Ming-Sheng Tung, Hsinchu City (TW); Hong-Ming Chen, Hsintien City (TW); Ching-Hsien Huang, Hsinchu (TW)

Correspondence Address: BIRCH STEWART KOLASCH & BIRCH, PO BOX 747, FALLS CHURCH, VA, 22040-0747, US

(73) Assignee: ProMOS Technologies Inc.

(21) Appl. No.: 11/258,115

(22) Filed: Oct. 26, 2005

(51) Int. Cl. H01L 21/8234; H01L 21/8238

(52) U.S. Cl. 438/199; 438/786; 438/275

(57) ABSTRACT

The present invention provides a method for preventing doped boron in a dielectric layer from diffusing into a substrate. First, at least one gate is formed on a periphery circuit area and a memory array area of a substrate, respectively, wherein the pattern density in the memory array area is higher than that in the periphery circuit area. Then, a barrier layer is formed on the memory array area and the periphery circuit area, and an undoped oxide barrier is formed on the periphery circuit area. Finally, a silicate glass containing boron is deposited on the memory array area and the periphery circuit area.

### BACKGROUND

1. Field of Invention

The present invention relates to a method for producing a semiconductor device. More particularly, the present invention relates to a method for preventing doped boron in a dielectric layer from diffusing into a substrate and for avoiding voids forming in the high-pattern-density area of the substrate.

2. Description of Related Art

Generally, a memory device comprises a periphery circuit area and a memory array area. The periphery circuit area has lower pattern density and usually comprises PMOS and NMOS. On the contrary, the memory array area has higher pattern density and usually uses only NMOS as a memory cell to constitute a memory device. The term “pattern density” means the ratio of gate area to non-gate area. (line to space)

Borophosphosilicate glass (BPSG) is a silicon oxide doped with boron and phosphorus and is a material commonly used for an inter-layer-dielectric layer in a semiconductor process. An undoped silicate glass (USG) usually exists under the BPSG layer to prevent doped boron in the BPSG from diffusing into the substrate to damage the electronic device. The diffusion of the boron has a serious effect, particularly on PMOS. Therefore, the thickness of the barrier layer in the periphery circuit area containing PMOS should be thick enough to prevent boron from diffusing into the substrate.

Since the sizes of electronic devices are becoming smaller and smaller, the pattern density on the substrate is becoming denser and denser, thereby increasing the aspect ratio, i.e. a ratio of a gate height to a gate space. Prior to the deposition of the BPSG, an undoped silicate glass is deposited on the substrate and acts as a barrier layer for preventing boron from diffusing into the substrate, which results in a further increase in the aspect ratio. Therefore, it is not easy for BPSG to fill the space between the gates in the memory array area, and voids are formed between the gates.

To resolve the two problems mentioned above, high-density silicon oxynitride or silicon nitride are used conventionally as a barrier layer to prevent boron from diffusing into the substrate. Because the silicon oxynitride or the silicon nitride has higher density than the USG, the thickness of the silicon oxynitride layer or the silicon nitride layer can be thinner, thereby reducing the aspect ratio and preventing voids from forming.

However, electronic devices are continuously developed toward smaller sizes. Consequently, the thickness of the silicon oxynitride layer or the silicon nitride layer becomes so thin that it is no longer sufficient to prevent boron from diffusing into the substrate. The device yield is thus decreased.

### SUMMARY

It is therefore an aspect of the present invention to provide a method for preventing doped boron in the dielectric layer from diffusing into a substrate. The method of the present invention can not only prevent voids from forming in a memory array area but also prevent boron from diffusing into a substrate in a periphery circuit area. More particularly, the semiconductor device of the present invention comprises an undoped oxide barrier that works together with a barrier layer in the periphery circuit area to prevent boron from diffusing into the substrate, and thus the thickness of the barrier layer can be reduced.

According to the present invention, because of the presence of the undoped oxide barrier in the periphery circuit area, the diffusion of the boron into the substrate can still be effectively avoided even though the thickness of the barrier layer is reduced. On the contrary, the memory array area does not comprise the undoped oxide barrier. Once the thickness of the barrier layer is reduced, the aspect ratio in the memory array area is reduced, and thus the formation of voids can be avoided in the subsequent process, e.g. the deposition of the boron-containing silicate glass.

In accordance with the foregoing aspect of the present invention, the present invention provides a method for preventing formation of voids and for preventing boron from diffusing into the substrate. First, a memory array area and a periphery circuit area are defined on a substrate. Then, at least one gate is formed in the memory array area and the periphery circuit area, respectively, wherein the pattern density in the memory array area is higher than that in the periphery circuit area. Subsequently, a barrier layer is formed in the memory array area and the periphery circuit area, which is followed by the formation of an undoped oxide barrier in the periphery circuit area. Finally, a boron-containing silicate glass is deposited in the memory array area and the periphery circuit area.

According to one preferred embodiment of the present invention, the formation of an undoped oxide barrier in the periphery circuit area is performed as follows. First, an undoped oxide barrier is formed in the memory array area and the periphery circuit area. Then, a photoresist is formed in the periphery circuit area. Next, the undoped oxide barrier in the memory array area is removed. Finally, the photoresist in the periphery circuit area is removed.

According to one preferred embodiment of the present invention, the barrier layer is a silicon nitride layer or a silicon oxynitride layer.

According to one preferred embodiment of the present invention, the undoped oxide barrier in the memory array area is removed by an etching process.

Accordingly, the method of the present invention has advantages especially when a substrate comprises both a memory array area and a periphery circuit area. In the present invention, the diffusion of boron into the substrate can be avoided in the periphery circuit area since an undoped oxide barrier is formed in the periphery circuit area. Furthermore, the aspect ratio in the memory array area can be reduced and the formation of voids in the memory array area can be avoided since the thickness of the barrier layer is reduced.

### BRIEF DESCRIPTION OF THE DRAWINGS

The invention can be more fully understood by reading the following detailed description of the preferred embodiments, with reference made to the accompanying drawings as follows:

FIG. 1A to FIG. 1D are cross-sectional views showing a flowchart of depositing a boron-containing silicate glass onto a silicon substrate according to a preferred embodiment of the present invention. FIG. 1D depicts a cross-sectional view of the semiconductor device according to a preferred embodiment of the present invention.

### DETAILED DESCRIPTION OF THE PREFERRED EMBODIMENTS

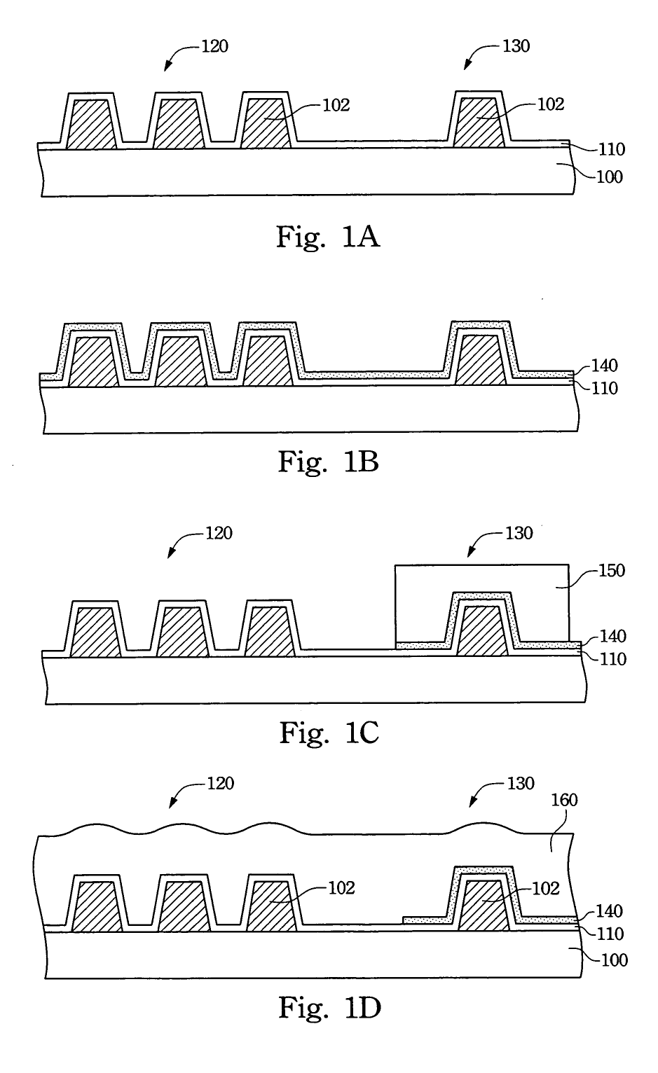

FIG. 1A to FIG. 1D are cross-sectional views showing a flowchart of depositing a boron-containing silicate glass onto a silicon substrate according to a preferred embodiment of the present invention.

In FIG. 1A, at least one gate 102 is formed in each of a memory array area 120 and in a periphery circuit area 130 of a substrate 100, respectively. A barrier layer 110 is formed in the memory array area 120 and the periphery circuit area 130. Preferably, the barrier layer 110 is a silicon nitride layer. The pattern density in the memory array area 120 is higher than that in the periphery circuit area 130, and is preferably higher than 1. The memory array area 120 is usually an area with higher pattern density and is not usually affected by boron diffusion because only NMOS is used in this area as memory cells. Conversely, the periphery circuit area 130 is usually an area with lower pattern density and where the diffusion of boron into the substrate must be avoided because PMOS is used in this area.

Referring to FIG. 1B, an undoped oxide barrier 140 is formed on the barrier layer 110. The undoped oxide barrier 140 can be made of any silicon oxide as long as the silicon oxide is not doped.

In FIG. 1C, a photoresist 150 is formed in the periphery circuit area 130, preferably by photolithography. Then, the undoped oxide barrier 140 in the memory array area 120 is removed, preferably by an etching process such as a wet etching process or a dry etching process. Subsequently, the photoresist 150 in the periphery circuit area 130 is removed.

In FIG. 1D, a boron-containing silicate glass 160, e.g. borophosphosilicate glass (BPSG) or borosilicate glass (BSG), is deposited in the memory array area 120 and the periphery circuit area 130, preferably by chemical vapor deposition (CVD).

The semiconductor device produced by the above mentioned method comprises at least one gate 102 in each of the memory array area 120 and the periphery circuit area 130 of the substrate 100, respectively, wherein the pattern density in the memory array area 120 is higher than that in the periphery circuit area 130. The pattern density in the memory array area 120 is preferably higher than 1. The semiconductor device further comprises a barrier layer 110 disposed above the memory array area 120 and the periphery circuit area 130, an undoped oxide barrier 140 disposed on the barrier layer 110 in the periphery circuit area 130, and a boron-containing silicate glass 160 disposed on the barrier layer 110 in the memory array area 120 and on the undoped oxide barrier 140 in the periphery circuit area 130.

Accordingly, the present invention avoids formation of voids in the memory array area and prevents boron from diffusing into the substrate in the periphery circuit area. Particularly, the present invention comprises an undoped oxide barrier on the barrier layer to work together with the barrier layer to prevent boron from diffusing into the substrate, and thus the thickness of the barrier layer can be reduced. According to the present invention, the diffusion of boron into the substrate can be avoided in the periphery circuit area because of the presence of the undoped oxide barrier. However, the memory array area does not comprise an undoped oxide barrier. Since the thickness of the barrier layer is reduced, the aspect ratio in the memory array area can be reduced and the formation of voids in the memory array area can be avoided in the subsequent process, e.g. the deposition of the boron-containing silicate glass.

The preferred embodiments of the present invention described above should not be regarded as limitations to the present invention. It will be apparent to those skilled in the art that various modifications and variations can be made to the present invention without departing from the scope or spirit of the invention. The scope of the present invention is as defined in the appended claims.

What is claimed is:

1. A method for forming a semiconductor device, wherein the method comprises:
forming at least a gate on a memory array area and a periphery circuit area of a substrate, respectively, wherein the pattern density in the memory array area is higher than that in the periphery circuit area;
forming a barrier layer on the memory array area and the periphery circuit area;
forming an undoped oxide barrier on the barrier layer in the periphery circuit area; and
depositing a boron-containing silicate glass in the memory array area and the periphery circuit area.

2. The method of claim 1, wherein the pattern density in the memory array area is higher than 1.

3. The method of claim 1, wherein the step of forming an undoped oxide barrier on the barrier layer in the periphery circuit area comprises:
forming a photoresist in the periphery circuit area;
removing the undoped oxide barrier in the memory array area; and
removing the photoresist in the periphery circuit area.

4. The method of claim 1, wherein the memory array area comprises a plurality of NMOS.

5. The method of claim 1, wherein the periphery circuit area comprises a plurality of PMOS.

6. The method of claim 1, wherein the barrier layer is a silicon nitride layer or a silicon oxynitride layer.

7. The method of claim 1, wherein the boron-containing silicate glass is a borophosphosilicate glass or a borosilicate glass.

8. The method of claim 3, wherein the undoped oxide barrier in the memory array area is removed by a wet etching process or a dry etching process.

9. The method of claim 1, wherein the boron-containing silicate glass is deposited in the memory array area and the periphery circuit area by chemical vapor deposition.
